(19) United States
(12) Patent Application Publication
(10) Pub. No.: US 2026/0363053 A1
(43) Pub. Date: Nov. 12, 2026

(54) POWER MESH SCHEME

(71) Applicant: Taiwan Semiconductor Manufacturing Company, Ltd., Hsinchu (TW)

(72) Inventors: I-Hsuan Kuo, Hsinchu (TW); Yi-Yang Chao, Hsinchu (TW); Pochun Wang, Hsinchu (TW); Wen Wei Chu, Hsinchu (TW); Chia-En Huang, Hsinchu (TW); Ting-Wei Chiang, Hsinchu (TW)

(73) Assignee: Taiwan Semiconductor Manufacturing Company, Ltd., Hsinchu (TW)

(21) Appl. No.: 19/200,460

(22) Filed: May 6, 2025

(51) Int. Cl. H10W 20/41; H10W 20/42; H10W 20/43

(52) U.S. Cl. CPC H10W 20/427; H10W 20/42; H10W 20/43; H10W 20/435

(57) ABSTRACT

An integrated circuit includes a first circuit to operate with a first supply voltage; a first power circuit to selectively provide the first supply voltage to the first circuit; a second circuit to operate with a second supply voltage; a second power circuit to selectively provide the second supply voltage to the second circuit; a first interconnect structure formed in a first one of a plurality of metallization layers over the major surface, wherein the first interconnect structure is to electrically couple the first power circuit to the first circuit; and a second interconnect structure formed in the first metallization layer, wherein the second interconnect structure is to electrically couple the second power circuit to the second circuit, wherein the first interconnect structure and the second interconnect structure are electrically isolated from each other with at least one isolation structure.

### BACKGROUND

Integrated circuit (IC) design encompasses a range of techniques for optimizing power management and enhancing device performance. Power management techniques can be implemented for reducing energy consumption, minimizing heat generation, or extending the operational life of electronic devices. For instance, techniques such as dynamic voltage and frequency scaling (DVFS) adjust the power supply and operating frequency based on the workload, for efficient energy usage. In certain IC (or memory) designs, a header can split to supply power to different functions, circuits, or devices. The partitioning of supply power can be based on a functional division of multiple power regions, such as non-active power (NAP) and switch rail. Neighboring devices or circuits in the IC may share power resources, e.g., from the same power line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a top view of an example integrated circuit, including circuits with single cell height, in accordance with some embodiments.

FIG. 1B illustrates a cross-sectional view of the example integrated circuit of FIG. 1A, in accordance with some embodiments.

FIG. 2A illustrates a cross-sectional view of the example integrated circuit of FIG. 1A including four power domains, in accordance with some embodiments.

FIG. 2B illustrates a cross-sectional view of the example integrated circuit of FIG. 2A, including two power domains, in accordance with some embodiments.

FIG. 3 illustrates a diagram of the example integrated circuit of at least one of FIGS. 1A-2B, including a stack of circuits partitioned into four power domains, in accordance with some embodiments.

FIG. 4 illustrates a diagram of the example integrated circuit of at least one of FIGS. 1A-2B, including a stack of circuits partitioned into two power domains, in accordance with some embodiments.

FIG. 5A illustrates a top view of an example integrated circuit, including one or more circuits with multiple cell heights, in accordance with some embodiments.

FIG. 5B illustrates a cross-sectional view of the example integrated circuit of FIG. 5A, in accordance with some embodiments.

FIGS. 6A-B illustrate diagrams of the example integrated circuit of at least one of FIGS. 5A-B, including circuits partitioned into two power domains, in accordance with some embodiments.

FIGS. 7-8 illustrate diagrams of the example integrated circuit of at least one of FIGS. 5A-B, including circuits partitioned into four power domains, in accordance with some embodiments.

FIG. 9 illustrates a diagram of the example integrated circuit of at least one of FIGS. 5A-B, including circuits partitioned into three power domains, in accordance with some embodiments.

FIG. 10 illustrates a diagram of the example integrated circuit of at least one of FIGS. 1A-B or FIGS. 5A-B, including variations in configurations of tiling cells to adjust the partitioning of power domains, in accordance with some embodiments.

FIGS. 11A-B illustrate diagrams of the example integrated circuit of at least one of FIGS. 1A-B or FIGS. 5A-B, including one or more transistors to short split power mesh (e.g., combining power domains), in accordance with some embodiments.

FIG. 12 illustrates a flow chart of an example method for forming an integrated circuit, in accordance with some embodiments.

FIG. 13 illustrates a flow chart of another example method for forming an integrated circuit, in accordance with some embodiments.

FIG. 14 illustrates a flow chart of yet another example method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In integrated circuit (IC) design such as memory design, a header can be utilized to supply power to various functions within the chip. The different functions can be achieved or executed via operations of one or more circuits within an IC. The header can operate as a switch or a power distribution network configured to control or otherwise manage power delivery to the one or more circuits or devices within the IC, e.g., ensuring that different parts/regions of the IC receive the desired power to operate or perform respective functions. For power delivery optimization, the header can split based on the functional division of the entire region. For example, the power supply can be divided/partitioned into different (power) domains, such as non-active power (NAP) and switch rail, via one or more headers. NAP can refer to regions of the IC that are not actively performing operations, which may consume relatively minimal power. The switch rail can supply power to active regions that consume relatively more energy/power compared to at least the non-active regions. Separating the power supply can facilitate the power distribution to different domains or reduce power wastage in the IC.

In certain layouts of the IC, such as a periphery sub-block layout, neighboring devices may operate at different supply voltages or power levels. The periphery sub-block layout can include peripheral circuits, such as but not limited to at least one of input/output (I/O) buffers, decoders, or sense amplifiers. The peripheral circuits can facilitate communication between a core logic of the IC and external interfaces, e.g., for managing power distribution or signal integrity. For example, one or more first devices may desire a relative larger power supplies to operate relative to other second devices. Such a demand for relatively larger power supplies in certain regions associated with the first device(s) may lead to competition for power resources. For instance, when multiple devices simultaneously consume relatively large amount of power, the power distribution network may be overloaded or strained, potentially causing voltage drops or power fluctuations. In this case, the competition for power resources may affect the performance or reliability of the devices, potentially leading to issues such as slower operation, increased heat generation, or reduced overall efficiency.

To address these challenges, the systems and methods of the technical solution discussed herein can split, divide, or otherwise partition a power domain of a device chain (e.g., including a plurality of circuits or devices) to ensure adjacent devices receive the desired power supply for the device operations. A power domain can refer to a group of devices, circuits, or components sharing the same power supply, which can be independently powered on or off. For example, the systems and methods can split the power domain of a chain of circuits into multiple power domains with at least one isolation structure (e.g., back-end-of-line (BEOL) metal with dielectric materials). Each power domain can include one or more circuits from the chain of circuits, for example. Splitting the power domain can prevent potential conflicts between devices or components with the IC, which are simultaneously consuming a relatively large power supply.

In further examples, the systems and methods can utilize the power supply from neighboring rows (or columns) of devices that are not in operation within a sub-block, or in some aspects, across sub-blocks. The devices can receive power supply from the neighboring rows or columns via one or more connections between power groups/domains. By splitting the power domain using at least one isolation structure and/or allowing/enabling utilization of the power supply from neighboring rows or columns, the systems and methods can avoid adjustment to the front end (FE) floorplan, power mesh can be shorten or split (via tiling configurations), and customize unit of power domain within the IC can be tailored to individual devices or groups of devices. Hence, the systems and methods of the technical solution can leverage the techniques or configurations discussed herein to provide a flexible power system, sub-cell level power domain splitting, and/or enhanced adjustment flexibility of power domain, among others.

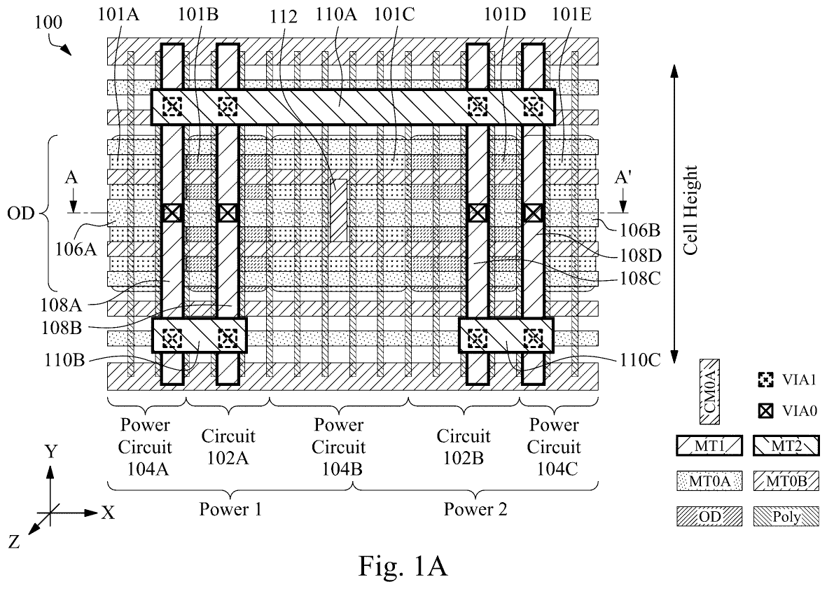

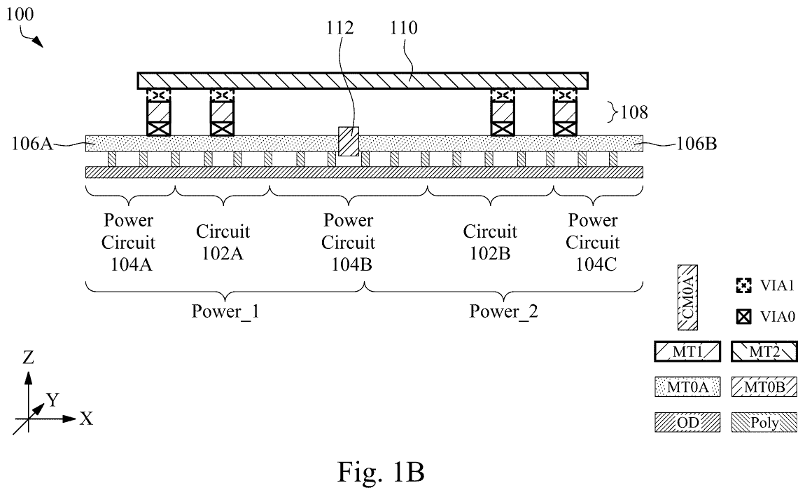

FIGS. 1A-B illustrate an example IC 100, including circuits with a single cell height, in accordance with some embodiments. FIG. 1A illustrates a top view of the example IC 100, in accordance with some embodiments. FIG. 1B illustrates a cross-sectional view of the example IC 100 of FIG. 1A, in accordance with some embodiments. For instance, FIG. 1B illustrates an example cross-sectional view of the IC 100 of FIG. 1A, cut along line A-A′. The IC 100 can include a plurality of devices formed in oxide diffusion (OD) area, region, or layer. The devices can be composed of one or more transistors, resistors, capacitors, or other components thereof. The devices can include, correspond to, or be referred to as circuits 102 (e.g., 102A-B). The devices can include power circuits 104 (e.g., 104A-C, sometimes referred to generally as circuits 104). The power circuit 104 can sometimes be referred to as a header configured to operate as a switch for controlling or managing power distribution to one or more circuits 102.

The OD can be an area within an IC where one or more transistors are fabricated. The fabricated transistors can be parts of the circuits 102, 104. For example, transistors can be interconnected to form one or more logic gates, amplifiers, memory cells, or other functional units. By controlling the flow of electrical signals, the transistors work together to execute computations, store data, or regulate power within the IC, e.g., perform the respective operations of the circuits 102, 104.

The OD can be formed along a major surface of a substrate (not shown). The circuits 102, 104 (or transistors), formed along the major surface of the substrate, can occupy regions 101A-E and may be referred to as front end (e.g., using a front-end of line (FEOL) process). For example, the circuits 102A-B can be formed in regions 101B, 101D, and the power circuits 104A-C can be formed in regions 101A, 101C, 101E, respectively. As shown, the power circuit 104B can be interposed between the circuits 102A-B along a lateral direction. The regions 101A-E can be referred to as first to fifth regions, respectively or in other non-limiting arrangements. The transistors can be fabricated or formed using any suitable deposition, etching, or masking technique(s), among other non-limiting fabrication techniques. The transistors can be composed of various materials, including but not limited to at least one of silicon, germanium, gallium arsenide, polysilicon, etc. It should be noted that the OD can include any number transistors or circuits 102, 104 to perform the intended features or functionalities of the IC 100, not limited to those discussed herein.

The circuits 102, 104 can be a part of at least one cell of the IC 100, such as a memory cell or other functional units. The circuits 102, 104 can be in a single cell height. The IC can include interconnect structures 106, 108, 110 (e.g., 106A-B, 108A-D, and 110A-C) that electrically connect devices within the IC 100. As shown in FIGS. 1A-B, the interconnect structures 106, 108, 110 can be labeled as metal track 0 (MT0 ), metal track 1 (MT1), and metal track 2 (MT2), respectively. For purposes of providing examples, MTO can represent metal tracks in layer 0 (e.g., first metallization layer). MT1 can represent metal tracks in layer 1 (e.g., second metallization layer). MT2 can represent metal tracks in layer 2 (e.g., third metallization layer), etc. The interconnect structures 106, 108, 110 can extend in preconfigured directions, such as a lateral direction, longitudinal direction, diagonal direction, vertical direction, etc.

The devices can receive electrical signals or supply power via at least one of the interconnect structures 106, 108, 110, e.g., allowing the devices to communicate and function independently or jointly. The interconnect structures 106, 108, 110 can be formed in the metallization layer(s). The metallization layers (and/or the interconnect structures 106, 108, 110) can be composed of a metal, such as aluminum, copper, gold, tungsten, or other suitable materials. Different interconnect structures 106, 108, 110 may be composed of similar or different materials. The metallization layers can be formed using a back end of line (BEOL) process. The metallization layer(s) can be formed over the FEOL or the OD layer. Individual metallization layers can be stacked over each other, e.g., a first metallization layer formed above/over the OD layer, a second metallization layer formed over the first metallization layer, a third metallization layer formed over the second metallization layer, etc. The first, second, third, or other metallization layers can be arranged in different orders.

The interconnect structures 106, 108, 110 in different metallization layers can be electrically coupled using via structures. For example, the interconnect structure 106 can be electrically coupled to the interconnect structure 108 using a first via structure (e.g., VIA1). In another example, the interconnect structure 108 can be electrically coupled to the interconnect structure 110 using a second via structure (e.g., VIA2).

The metallization layer(s) can be used to create the electrical pathways within the IC 100. For purposes of providing examples, the interconnect structure(s) 106 of the first metallization layer can supply power from a power source (e.g., VDD or VSS) (not shown). The power source can be an internal power source to the IC 100 or an external power source from the IC 100. The power supply to the circuits 102 can be managed by one or more power circuits 104 (e.g., header(s)) or other components configured to distribute power to different regions of the IC 100.

For example, the power circuit 104A can be electrically coupled to the circuit 102A and the power circuit 104C can be electrically coupled to the circuit 102B. In some cases, the power circuit 104B can be electrically coupled to at least one of the circuits 102. The circuits 102 and the power circuits 104 can be electrically coupled to the at least the interconnect structure 106. The power circuits 104 can operate for instance as a switch to control power supply from the interconnect structure 106 for distribution to the respective circuits 102, which may operate with the same or different supply voltage, for example. As an illustrative example, regions 101B, 101D associated with the circuits 102A-B can be presented in different sizes, where smaller region represent relatively lower power consumption during execution of the circuit operation and larger region represent relatively higher power consumption during execution of the circuit operation, for example. It should be noted that circuits 102 operating at different voltage or power level may be presented in similar sized regions, or a circuit operating at a lower power level compared to another circuit may be associated with a relatively smaller region in the IC 100, e.g., the region sizes do not need to reflect the power consumption level of the circuits 102.

The circuits 102, 104 can electrically connect to at least the interconnect structure 106 via a plurality of connections, e.g., composed of polysilicon (poly) or other suitable materials. For instance, polysilicon can be used to form gate structures of transistors for electrical connections between components in the IC 100. Other power circuits 104 can be electrically coupled to the one or more circuits 102. The IC 100 can include more or less power circuits 104 and/or circuits 102 (e.g., devices) to perform the predefined/preconfigured functions.

The circuits 102 can be charging devices. In certain aspects, the circuits 102 may compete for the power supply during operation, for instance, when connected to the same power domain or power group. To prevent or avoid the competition for power resources, an isolation structure 112 can be formed to separate power domains (e.g., into Power_1 and Power_2) through the power circuits 104. For example, the isolation structure 112 can include or correspond to a metal layer (e.g., CMOA). The isolation structure 112 can be formed during the BEOL process using non-conductive materials, such as any suitable dielectric materials. The isolation structure 112 can be composed of other materials, not limited to those discussed herein. The isolation structure 112 can be formed between portions of the interconnect structure 106 delivering electrical power or voltage to the circuits 102, 104. For instance, after forming the interconnect structure 106 (e.g., MTO), a directional etching can be executed to cut the MTO, forming an opening. Then, the opening can be filled with a dielectric material (e.g., the isolation structure 112), thereby electrically isolating the separated portions (e.g., 106A, 106B) of the interconnect structure 106. The isolation structure 112 can be disposed or formed over the power circuits 104B or the region 101C.

For instance, the isolation structure 112 can electrically isolate portions of the interconnect structure 106 into interconnect structure 106A (e.g., first interconnect structure, labeled as MTOA) and interconnect structure 106B (e.g., second interconnect structure labeled as MTOB). The isolation structure 112 can split the interconnect structure 106 to create distinct power domains that can be independently controlled, e.g., a first power domain associated with the interconnect structure 106A and a second power domain associated with the interconnect structure 106B. The interconnect structure 106A can be configured to electrically couple the power circuit 104A to the circuit 102A. The interconnect structure 106B can be configured to electrically couple the power circuit 104C to the circuit 102B. In some cases, at least one of the interconnect structures 106B can be configured to electrically couple the power circuit 104B to at least one of the circuits 102. The circuits 102 can be connected to their respective power domains via the power circuits 104 (e.g., headers) to ensure that each circuit 102 receives the respective operating supply voltage, e.g., a first supply voltage for the circuit 102A and a second supply voltage for the circuit 102B.

By splitting the power domain using the isolation structure 112, a new FE floorplan is not required and sub-cell level power domain splitting can be achieved, reducing interference and competition for power resources between adjacent devices. In various implementations, the IC 100 can include additional isolation structures, interconnect structures, metallization layers, or other components thereof. It should also be noted that numbering of any components discussed herein, such as “first,” “second,” “third,” etc., of the circuits, power circuits, devices, interconnect structures, isolation structures, etc., are for purposes of providing examples, and does not restrict/limit the structure to any specific order, thereby such numbering are interchangeable, such as a first component may sometimes be referred to as a second component, a third component, or others, in certain examples.

For purposes of providing examples, the IC 100 can include vertical interconnect accesses (VIAs) (e.g., sometimes referred to as via structures), such as VIA0 and VIA1, among others, for connection between interconnect structures in different metallization layers. The metallization layers can be stacked vertically, horizontally, or diagonally. The partitioned interconnect structures 106A-B can be electrically coupled to each other with one or more of the interconnect structures 108, 110. For example, the interconnect structures 106 can extend in a lateral direction in the first metallization layer over the OD or the major surface of the substrate. The interconnect structure(s) 108 can be formed in the second metallization layer over the first metallization layer, extending in another lateral direction perpendicular to the interconnect structures 106. The interconnect structure(s) 108 can electrically couple to the interconnect structure(s) 106 with VIA1. The interconnect structure 110 can be formed in the third metallization layer over the second metallization layer, extending in the lateral direction perpendicular to the interconnect structures 108. The interconnect structure 110 can extend in the same lateral direction as the interconnect structures 106. The interconnect structure 110 can electrically couple to the interconnect structures 108 with VIA2. As shown in at least FIG. 1B, as an example, the interconnect structure 106A and the interconnect structure 106B can be electrically coupled to each other with at least the interconnect structure 110. The interconnect structures 106, 108, 110 can facilitate efficient power and signal distribution across the IC 100.

With the separated power domains, each circuit 102 within the IC 100 can operate at its desired (e.g., optimal) power level. The power domains can be isolated from each other, preventing power leakage and ensuring that each region receives the appropriate power supply based on the circuit operation. As such, the systems and methods can enhance the efficiency and performance of the IC 100, by increasing the precision of control over power distribution and reducing the risk of voltage drops, among others. In various configurations, the IC 100 can include more or less components discussed herein.

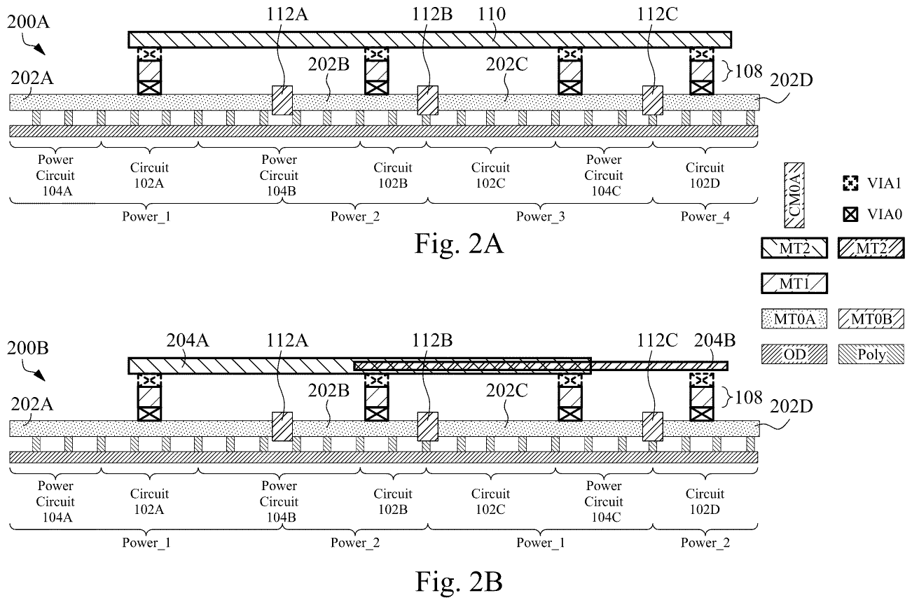

FIG. 2A illustrates a cross-sectional view of the example IC 100 of FIG. 1A, including four power domains, in accordance with some embodiments. FIG. 2A provides an example IC 200A comprising one or more components, structures, or features similar to (or different from) the IC 100 of FIG. 1A. The IC 200A can include a different configuration, arrangement, or layout compared to the IC 100. In various configurations, individual ICs discussed herein (e.g., FIGS. 2A-11B) may include similar and/or different components, layouts, arrangements, features, or functionalities relative to each other, such as similar circuits/devices and the circuit operation thereof, varying layouts or arrangements of components, similar or different number of power domains, or similar number of power circuits, to illustrate various example configurations. The various ICs illustrated herein are provided as non-limiting examples, e.g., more or less components can be added, different arrangements, configurations, or interconnections can be configured, etc.

The IC 200A can include circuits 102A-D (e.g., sometimes referred to generally as circuit(s) 102). The circuits 102 can include or be composed of transistors. Individual circuits 102 can be configured to perform respective operations, operating at predefined supply voltage. For instance, the circuits 102A-D can operate at first to fourth supply voltages, respectively. In some cases, two or more circuits 102 can operate at the same supply voltage. Similar to the circuits 102 in FIGS. 1A-B, the circuits 102 can be disposed or fabricated in the OD, each (electrically) connected to the interconnect structures 202A-D (e.g., sometimes referred to as interconnect structure(s) 202, e.g., CMOA) via the plurality of connections (e.g., poly).

As shown in FIG. 2A, the interconnect structure 202 can be split, divided, or partitioned into four parts, corresponding to four power domains (e.g., Power_1, Power_2, Power_3, and Power_4). The interconnect structures 202A-D can be electrically isolated from each other with the isolation structures 112A-C. The individual isolation structures 112A-C may be composed of similar or different materials for electrically isolating the interconnect structures 202. By isolating the interconnect structures 202, the power domain (or power supplier groups) can be separated, e.g., into four power domains or four parts of the power supplier groups.

Individual power circuits 104 can be electrically coupled to at least one of the circuits 102 to control power distribution to the circuits 102, e.g., the power circuit 104 may operate as a switch for distributing/providing supply voltage or prevent/cut supply voltage to the respective circuit(s) 102. The interconnect structures 202 can facilitate the electrical connections between the power circuits 104 and the circuits 102. For example, the interconnect structure 202A may be configured to electrically couple the power circuit 104A to the circuit 102A. The interconnect structure 202B may be configured to electrically couple the power circuit 104B or 104C to the circuit 102B. The interconnect structure 202C may be configured to electrically couple the power circuit 104B or 104C to the circuit 102C. The interconnect structure 202D may be configured to electrically couple the power circuit 104C to the circuit 102D, for example. Other arrangements of the electrical connections between the interconnect structures 202, the power circuits 104, and the circuits 102 may be configured, not limited to the example connections herein.

The individual interconnect structures 202 can be electrically coupled to other interconnect structures 108, 110 with the via structures, e.g., VIA0 and/or VIA1. The interconnect structure 110 can be electrically coupled to the interconnect structures 108 with VIA1. The interconnect structures 108 can be coupled to the interconnect structures 202 with VIA2. The interconnect structures 202 can extend in the same lateral direction as the interconnect structure 110. The interconnect structure 108 can extend in a direction perpendicular to the interconnect structures 202, 110. The interconnect structures 108, 110, 202 may be formed or arranged to extend in other directions. With these electrical connections, the individual interconnect structures 108A-D can be electrically coupled to each other with at least the interconnect structure 110.

The circuits 102A-D can send or receive electrical signals between each other via at least the interconnect structure 110. By separating the power domains, the IC 200A can prevent the circuits 102A-D from competing over the power resources. In various cases, the partitioned power domains can be combined, shorted, or connected to each other via at least one interconnect structure, e.g., shorting or coupling certain power circuits 104 or power supply lines between different power domains, such as described in conjunction with but not limited to FIG. 2B.

FIG. 2B illustrates a cross-sectional view of the example integrated circuit of FIG. 2A including two power domains, in accordance with some embodiments. The IC 200B of FIG. 2B can include one or more components, features, or functionalities of the IC 200A of FIG. 2A and/or the IC 100 of FIGS. 1A-B. In some cases, the IC 200B can include additional or different components from the other ICs of at least one of FIGS. 1A-2A.

The IC 200B can include the circuits 102, the power circuits 104, and the interconnect structures 202 separated into four power domains with the isolation structures 112, similar to the IC 200A. In this illustrative example, pairs of power domains can be combined or grouped together, sharing the power supply. For example, at least a portion of the interconnect structure 202A can be electrically coupled to at least a portion of the interconnect structure 202C, to share the power domain (e.g., Power_1). Further, at least a portion of the interconnect structure 202B can be electrically coupled to at least a portion of the interconnect structure 202D, to share another power domain (e.g., Power_2). In such cases, the power supplier groups of the interconnect structure 202 (e.g., MTO) can be separated into two parts or two power domains.

In FIG. 2B, interconnect structures 204A-B (e.g., sometimes referred to as interconnect structure(s) 204) can be formed in the third metallization layer above the second metallization layer (e.g., including the interconnect structures 108). The interconnect structures 204 can be composed of materials similar to or different from the interconnect structure 110. The interconnect structure 204A can be configured to electrically couple the interconnect structure 202A (associated with the first power domain) to the interconnect structure 202C. The interconnect structure 204B can be configured to electrically couple the interconnect structure 202B (associated with the second power domain) to the interconnect structure 202D.

The circuits 102A, 102C sharing the first power domain can be separated or interposed by the circuit 102B, sharing the second power domain with the circuit 102D. Similarly, the circuits 102B, 102D sharing the second power domain can be separated or interposed by the circuit 102C. The connections between the interconnect structures 202, 204 may be through at least the interconnect structures 108 (or other intermediate interconnect structures). In some configurations, the interconnect structures 202 can be connected directly to the interconnect structures 204 with a via structure. The coupling between the pairs or groups of interconnect structures 202A, 202C or interconnect structures 202B, 202D can include or involve shorting the power lines to the respective circuits 102, allowing shared power domains. As such, the four power domains of FIG. 2A can be combined into two power domains as in FIG. 2B.

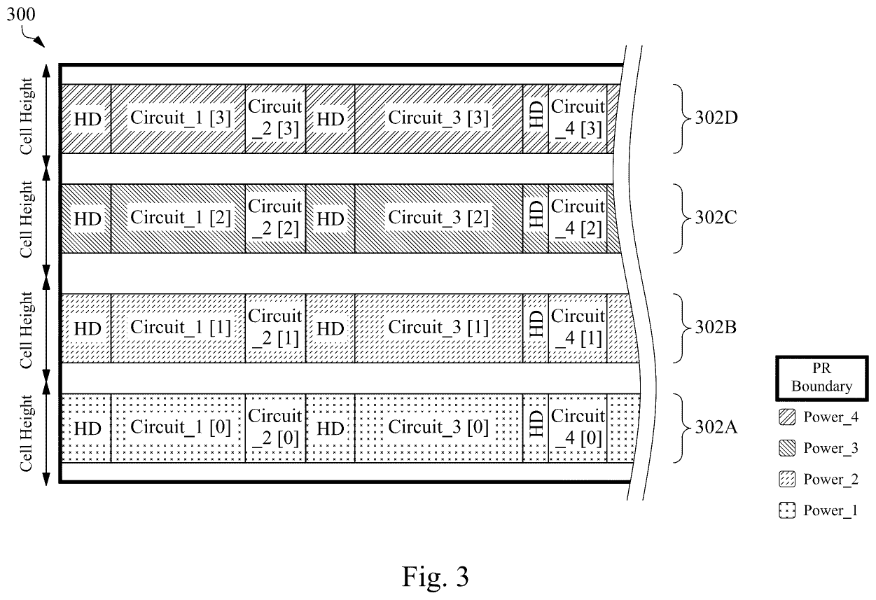

FIG. 3 illustrates a diagram of the example integrated circuit of at least one of FIGS. 1A-2B, including a stack of circuits partitioned into four power domains, in accordance with some embodiments. FIG. 3 includes an IC 300. The IC 300 can be fabricated within the place and route boundary (PR boundary). The PR boundary can represent a designated area within a layout where the placement of transistors and routing of connections are allowed, e.g., the active region with certain design rules. The IC 300 can include a stack of transistors or circuits (e.g., Circuit_1[0]-[3] to Circuit_4[0]-[3]) within the PR boundary. The circuits of the IC 300 can correspond to or include components, features, or functionalities of the circuits 102 described in conjunction with at least one of but not limited to FIGS. 1A-2B, for example. The IC 300 can include a plurality of headers (HDs). The HDs can correspond to or include components, features, or functionalities of the power circuits 104, described in conjunction with at least one of but not limited to FIGS. 1A-2B, for example.

The stack of transistors of the IC 300 can include a plurality of layers 302A-D (e.g., sometimes referred to as layer(s) 302). In some cases, each layer 302 of the stack of circuits can represent an individual IC. The circuits in each layer 302 of the stack can have a single cell height. Individual layers 302 can include various circuits (e.g., Circuits_1 to Circuits_4), each of the circuits coupled to a respective headers (or power circuits). The HD can control or manage power distribution to one or more circuits within the same or different power domains. Although four example circuits (or devices) and three example HDs are provided, more or less number of circuits or HDs can be fabricated or formed from the fabricated transistors. The interconnections or coupling between circuits and/or HDs can be described in conjunction with but not limited to at least one of FIGS. 1A-2B.

In some configurations, each layer 302 of the stack can be in respective power domains, e.g., MTO power supplier groups separated into four parts (or layers 302). For example, the circuits (including HDs) of layer 302A can be in (or associated with) a first power domain (e.g., Power_1). The circuits of layer 302B can be in a second power domain (e.g., Power_2). The circuits of layer 302C can be in a third power domain (e.g., Power_3). The circuits of layer 302D can be in a fourth power domain (e.g., Power_4). The power supply line (e.g., the interconnect structure 106, 202) can be coupled to one or more transistors (e.g., p-type metal-oxide-semiconductor (PMOS), n-type metal-oxide-semiconductor (NMOS), or other types of metal-oxide-semiconductor field-effect-transistor (MOSFETs)) of the HDs, configured to activate or deactivate to transmit power to one or more circuits. For instance, circuits within the same power domain may be connected to the same PMOS of at least one HD to receive supply voltage from the same power supply. In another example, the HD can include multiple transistors (e.g., multiple PMOS), each PMOS configured to supply voltage from a respective power supply to operate different circuits or devices. In some cases, one or more circuits may communicate with other circuits in the same or different layers 302. In some other cases, one or more circuits may be communicatively isolated from (e.g., not in communication with) other circuits within the same or different layers 302.

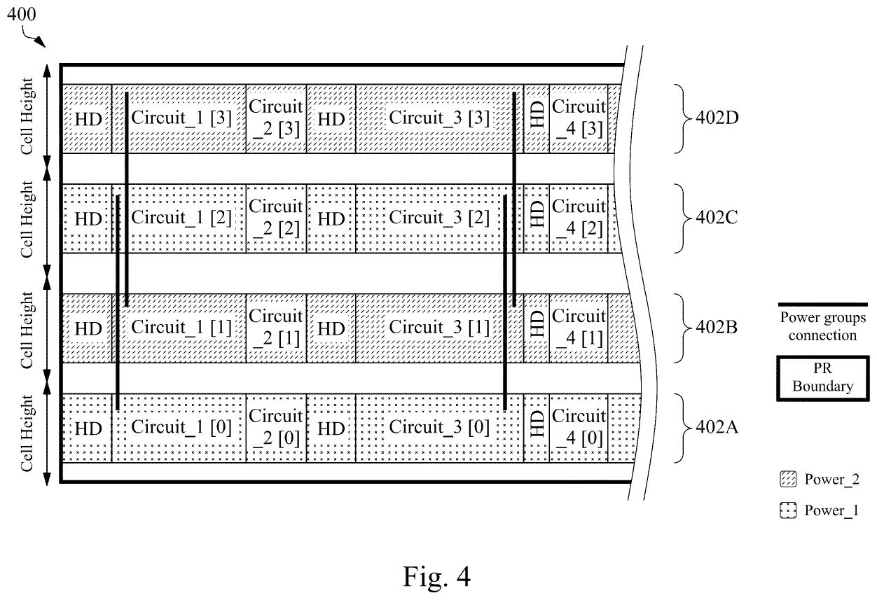

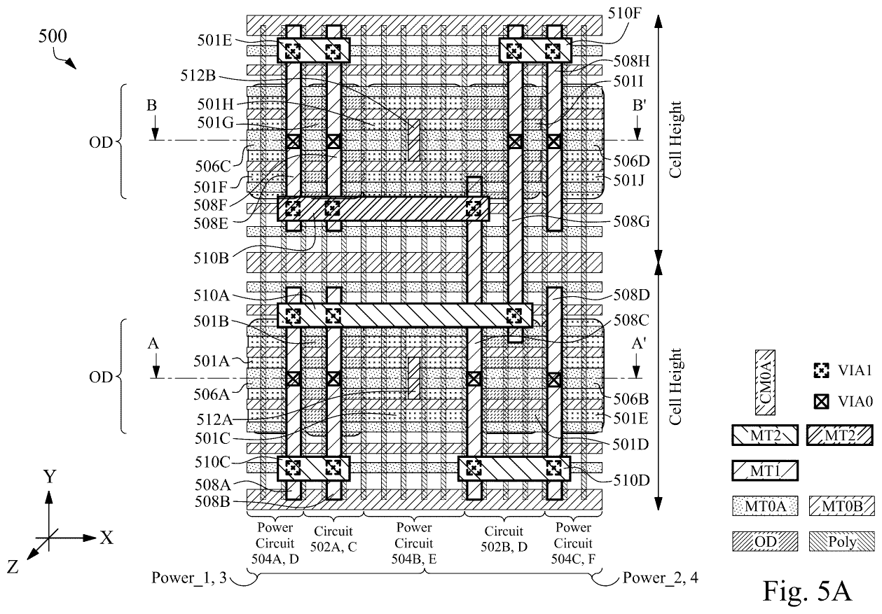

FIG. 4 illustrates a diagram of the example integrated circuit of at least one of FIGS. 1A-2B, including a stack of circuits partitioned into two power domains, in accordance with some embodiments. FIG. 4 includes an IC 400 fabricated within the PR boundary. The IC 400 can include one or more components similar to at least IC 300, as described in conjunction with at least FIG. 3. The IC 400 can include a stack of circuits or devices separated into layers 402A-D (e.g., sometimes referred to as layer(s) 402). The IC 400 (or other ICs) can include more or less layers of circuits within the stack.

In various configurations, the circuits within the stack can be separated into two power domains or power groups using at least one connection (e.g., power groups connection). The power groups connection can represent, for instance, an interconnect structure, a wire, or other coupling components configured to electrically couple at the power line from one power domain to another or to couple the transistors which supply power in different power domains, e.g., integrating the power domains into a single power domain, for example. In this case, the power groups connections (e.g., one or more interconnect structures) can be formed, deposited, or established to couple power domains between layer 402A and layer 402C. Between layers 402A, 402C, the IC 400 can include a first power domain (e.g., Power_1). The power groups connection can be configured to couple power domains between layer 402B and layer 402D for sharing the power supply. Hence, between layers 402B, 402D, the IC 400 can include a second power domain (e.g., Power_2). In some other configurations, the power groups connection may couple between different layers, such as between layers 402A, 402D or layers 402B, 402C, for example. Providing the power groups connection to combine the power groups or power domains, the systems and methods of the technical solution can enhance adjustment flexibility of the power domain for a flexible power system.

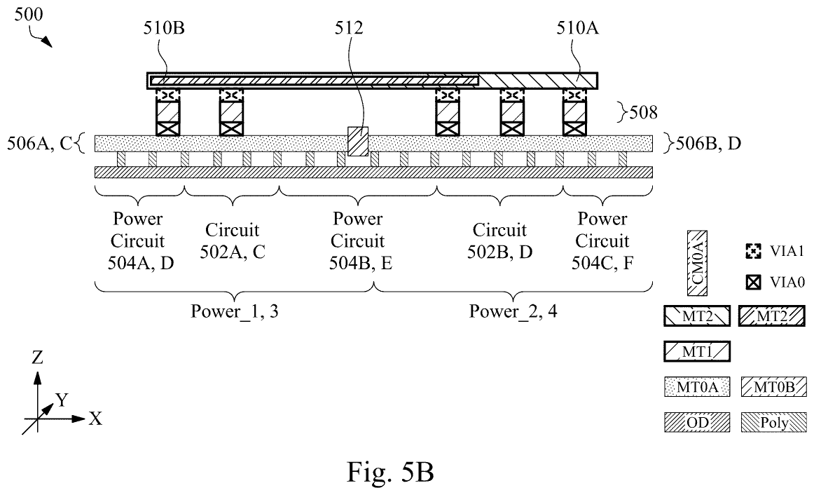

FIGS. 5A-B illustrate an example IC 500, including one or more circuits with multiple cell heights, in accordance with some embodiments. FIG. 5A illustrates a top view of the example IC 500, in accordance with some embodiments. FIG. 5B illustrates a cross-sectional view of the example IC 500 of FIG. 5A, cut along line A-A′ or line B-B′, in accordance with some embodiments. The circuit with multiple cell heights can refer to a device or circuit with at least a portion of the device extending beyond a single cell height, such as shown in at least FIGS. 5A-B. One or more components or functions of IC 500 can be similar to (or in some cases different from) other ICs discussed herein (e.g., at least one of IC 100, 200A, 200B, etc.).

As shown, FIGS. 5A-B include a plurality of transistors fabricated or formed in the OD on the major surface of the substrate (not shown). The transistors in the OD can include, correspond to, or be a part of at least one of the circuits/devices 502A-D (e.g., sometimes referred to as circuit(s) 502) and/or power circuits 504A-F (e.g., sometimes referred to as power circuit(s) 504). In a first cell height, the power circuit 504A, circuit 502A, power circuit 504B, circuit 502B, and power circuit 504C can be fabricated in regions 501A-E, respectively. In a second cell height, the power circuit 504D, circuit 502C, power circuit 504E, circuit 502D, and power circuit 504F can be fabricated in regions 501F-J.

The IC 500 can include interconnect structures 506A-D, 508A-H, 510A-B formed in metallization layers. The interconnect structures 506A-D can sometimes be referred to as interconnect structure(s) 506. The interconnect structures 508A-H can sometimes be referred to as interconnect structure(s) 508. The interconnect structures 510A-B can sometimes be referred to as interconnect structure(s) 510. The interconnection structures 506, 508, 510 can be composed of materials similar to or different from the interconnect structures 106, 108, 110, described in conjunction with at least one of but not limited to FIGS. 1A-B.

The interconnection structures 506, 508, 510 can be formed above the OD. For example, the interconnect structures 506 (and other MTOA and MTOB structures) can be formed in the first metallization layers over the OD, extending in a first lateral direction. The interconnect structures 508 can be formed in the second metallization layer over the first metallization layer, extending along a second lateral direction perpendicular to the first lateral direction. The interconnect structures 510 can be formed in the third metallization layer over the second metallization layer, extending along the first lateral direction, e.g., parallel to the interconnect structures 506. One or more interconnect structures 506, 508, 510 can be electrically coupled to each other with the via structures (e.g., VIA0, VIA1, etc.).

The interconnect structures 506 can carry power supply from one or more power sources for distribution to the circuits 502, 504. To prevent the competition for power resources, the interconnect structures 506 can be split/partitioned/divided to separate the circuits 502, 504 into different power domains. The interconnect structures 506 can be split into multiple portions with one or more isolation structures 512A-B (e.g., sometimes referred to as isolation structure(s) 512). For example, the isolation structure 512A can split the interconnect structure 506 in the first cell height into interconnect structures 506A-B. The isolation structure 512B can split the interconnect structure 506 in the second cell height into interconnect structures 506C-D. The isolation structures 512A-B can be formed over regions 501C, 501H or power circuits 504B, 504E, respectively. In such configurations of electrically isolating portions of the interconnect structure 506, four power domains can be established in the IC 500, e.g., across the cell heights. For instance, the circuit 502A-D can be associated with the first to fourth power groups or power domains, respectively.

The interconnect structure 510A can electrically couple the interconnect structure 506A to the interconnect structure 506B. The interconnect structure 510B can electrically couple the interconnect structure 506C to the interconnect structure 506D. The interconnect structures 508 can be interposed between the interconnect structures 506, 510. The power connection of the interconnect structure(s) 508 (e.g., MT1) can be disconnected. In some implementations, disconnecting the power connection of the interconnect structure(s) 508 may disconnect or prevent power supply to at least one of the interconnect structures 506 (e.g., MTO). The interconnect structures 508 (e.g., MT2 lines) can be connected in a crisscross pattern, e.g., the connections between the power supply lines can be in an alternating or intersecting manner. The crisscross connection can prevent any overlap or intersection of the power supply lines, ensuring that the power domains remain separate or electrically isolated from each other, for example. The IC 500 can include more or less components, cells, electrical connections, etc. The components of the IC 500 can be arranged in different configurations or layouts.

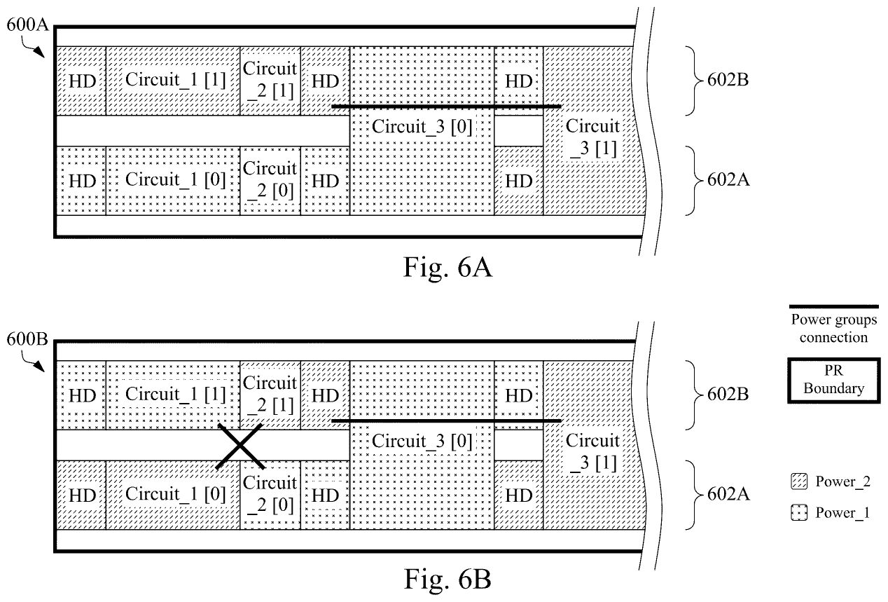

FIGS. 6A-B illustrate diagrams of the example integrated circuit of at least one of FIGS. 5A-B, including circuits partitioned into two power domains, in accordance with some embodiments. FIGS. 6A-B can include ICs 600A-B, respectively, comprising one or more components or features similar to or different from at least the IC 500, such as described in conjunction with FIGS. 5A-B. The ICs 600A-B can include a stack of devices/circuits, e.g., devices in layers 602A-B (e.g., sometimes referred to as layer(s) 602). The stack of circuits can include HDs to control power supply for one or more circuits. The circuits can operate in response to receiving respective predefined supply voltages. One or more circuits can include multiple cell heights, such as Circuit_3 [0] and Circuit_3 [1] extending across the layers 602. The transistors (as part of the circuits or HDs) can be fabricated within the PR boundary.

The ICs 600A-B can include two power domains (e.g., Power_1 and Power_2). Different arrangements or connections to establish the two power domains can be provided between ICs 600A-B. For example, the IC 600A can include a power groups connection coupled between the Circuit_2[1] (or the corresponding HD) and the Circuit_3[1], to share power supply. The power groups connection can be coupled to the transistors, e.g., PMOS or other types of MOSFET, controlling power supply to the respective circuits, such that the associated circuits share the power resources within the same power domain. In this case, the first power domain can include Circuit_1 [0], Circuit_2 [0], and Circuit_3 [0], and the second power domain can include Circuit_1 [1], Circuit_2 [1], and Circuit_3 [1].

In another example, the IC 600B can include other power groups connections (in addition to the power groups connection of the IC 600A), such as between Circuit_1 [0] and Circuit_2 [1] and between Circuit_1 [1] and Circuit_2 [0]. By establishing the connection, the Circuit_1 [0] can be part of the second power domain and the Circuit_1[1] can be a part of the first power domain, for example. Other example arrangements of connections can be provided in the non-limiting examples herein.

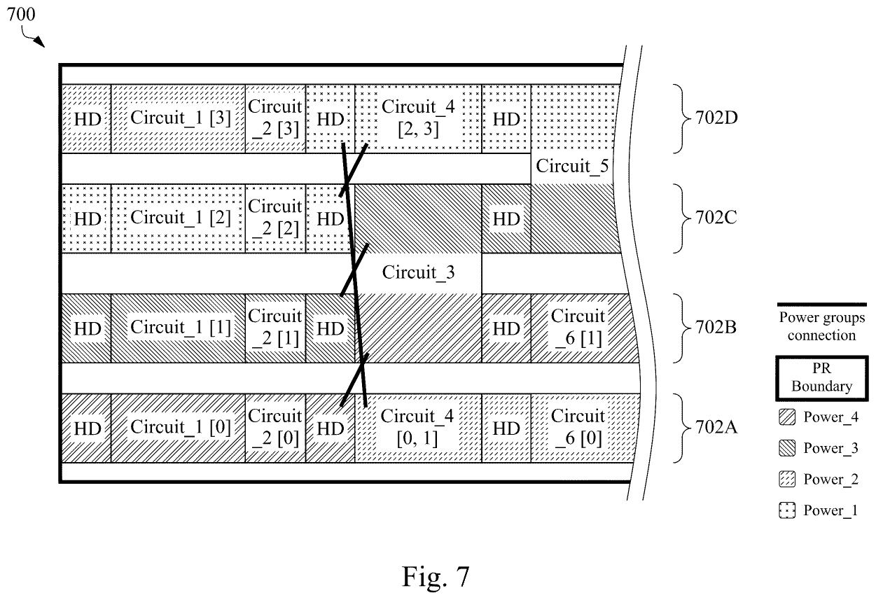

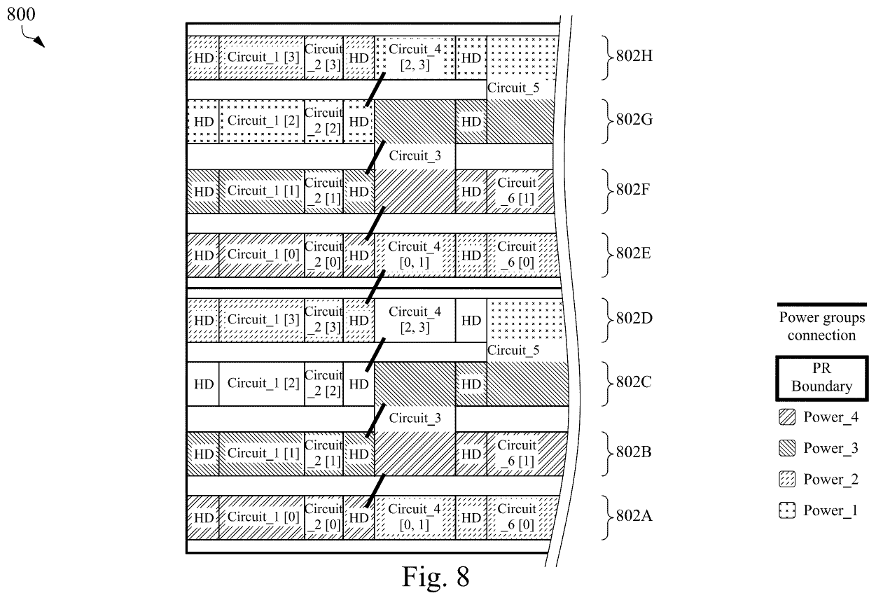

FIGS. 7-8 illustrate diagrams of the example integrated circuit of at least one of FIGS. 5A-B, including circuits partitioned into four power domains, in accordance with some embodiments. FIGS. 7-8 include ICs 700, 800, respectively, each comprising components, features, or functionalities similar to or different from at least one of but no limited to ICs 500, 600A-B, described in conjunction with FIGS. 5A-6B. The IC 700 can include a stack of circuits/devices formed within a PR boundary. In this case, the IC 700 can include four layers 702A-C (e.g., sometimes referred to as layer(s) 702) of circuits. The IC 800 can include a stack (or multiple stacks) of circuits formed in multiple PR boundaries. In this case, the IC 800 can include eight layers 802A-H (e.g., sometimes referred to as layer(s) 802) of circuits.

The ICs 700, 800 can provide various layouts or arrangements of interconnections between circuits or HDs to short or combine different power domains using the power groups connections. The power group connections can be connected to circuits in different layers 702, 802. In some cases, different portions of a circuit (e.g., Circuit_3 and Circuit_5) can in different power domains, e.g., operating at different supply voltages.

For example, the IC 700 can include four power domains. The first power domain (e.g., Power_1) can include Circuit_1 [2] and Circuit_2 [2] coupled to Circuit_4 [2, 3] and a portion of Circuit_5. The second power domain (e.g., Power_2) can include Circuit_1 [3] and Circuit_2 [3] coupled to Circuit_4 [0, 1] and Circuit_6 [0]. The third power domain (e.g., Power_3) can include Circuit_1 [1] and Circuit_2 [1] coupled to a portion of Circuit_3 and a portion of Circuit_5. The fourth power domain can include Circuit_1 [0] and Circuit_2 [0] coupled to a portion of Circuit_3 and Circuit_6 [1]. The power connection of MT1 can be disconnected. The power nets can be connected in crisscross mode, such as described hereinabove.

The IC 800 can include four power domains. The interconnections of IC 800 between circuits in different layers 802 can be similar, at least in part, to those in at least the IC 700 of FIG. 7, for example. In this case, the IC 800 can include one or more power groups connections to electrically couple circuits in different PR boundaries (e.g., connection between different stacks of circuits). As shown as an example to establish the second power domain (e.g., Power_2), the power groups connection can connect Circuit_1 [3] and Circuit_2 [3] in a first stack (e.g., first PR boundary, including layers 802A-D) to Circuit_4 [0, 1] and Circuit_6 [0] in a second stack (e.g., second PR boundary, including layers 802E-H). Other connections can be configured for combining power domains or connecting certain circuits to a particular power domain.

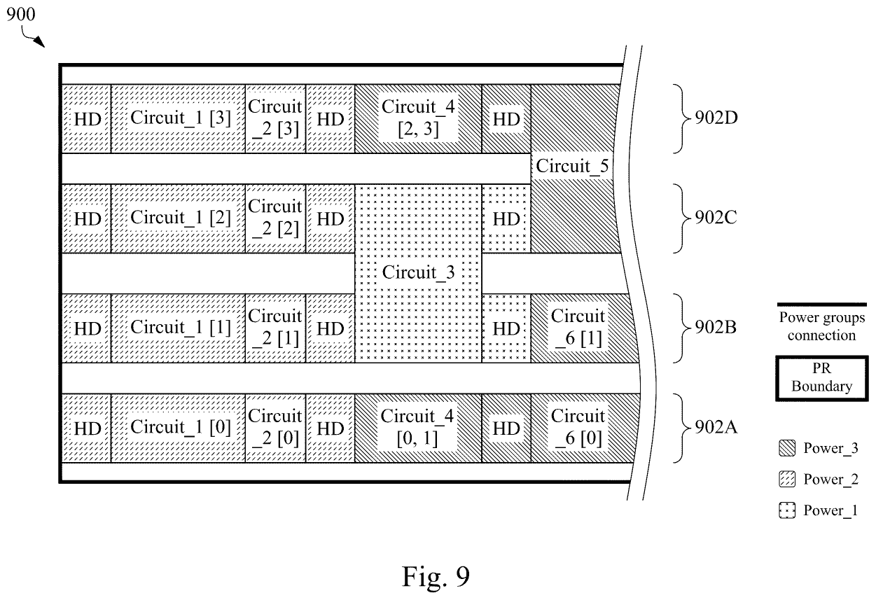

FIG. 9 illustrates a diagram of the example integrated circuit of at least one of FIGS. 5A-B, including circuits partitioned into three power domains, in accordance with some embodiments. FIG. 9 includes an IC 900. The IC 900 can include one or more components, features, or functions similar to or different from at least one of but not limited to the ICs 500, 600, 700, 800 of FIGS. 5A-8. The IC 900 can include a stack of circuits in layers 902A-D. The IC 900 can include circuits with multiple cell heights, e.g., Circuit_3 and Circuit_5. The IC 900 can split the power domain into three power domains (e.g., Power_1, Power_2, and Power_3). The IC 900 can include an example layout of circuits and connections to establish the three power domains.

For example, the first power domain can include Circuit_3 (and the associated HDs). The second power domain can include Circuit_1 [0]-[3] and Circuit_2 [0]-[3]. The interconnection between these circuits may be described in conjunction with at least FIGS. 5A-B, for example. The circuits can be electrically coupled via one or more interconnect structures or wiring, for example. In this example, the third power domain can include Circuit_4 [0, 1, 2, 3], Circuit_5, and Circuit_6 [0]-[1]. The power groups connection can be configured to electrically couple the Circuit_4 [0, 1] to Circuit_4 [2, 3]. The power groups connection can extend across (or over) Circuit_3. In various implementations, the power groups connection(s) can extend across other circuits or interconnect structures, discussed herein, e.g., extending over or under certain components or structures.

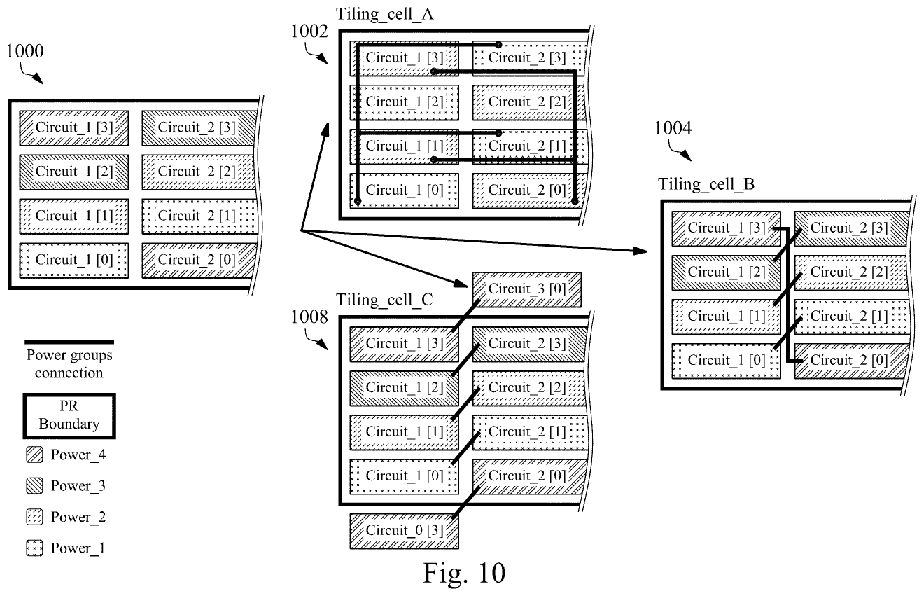

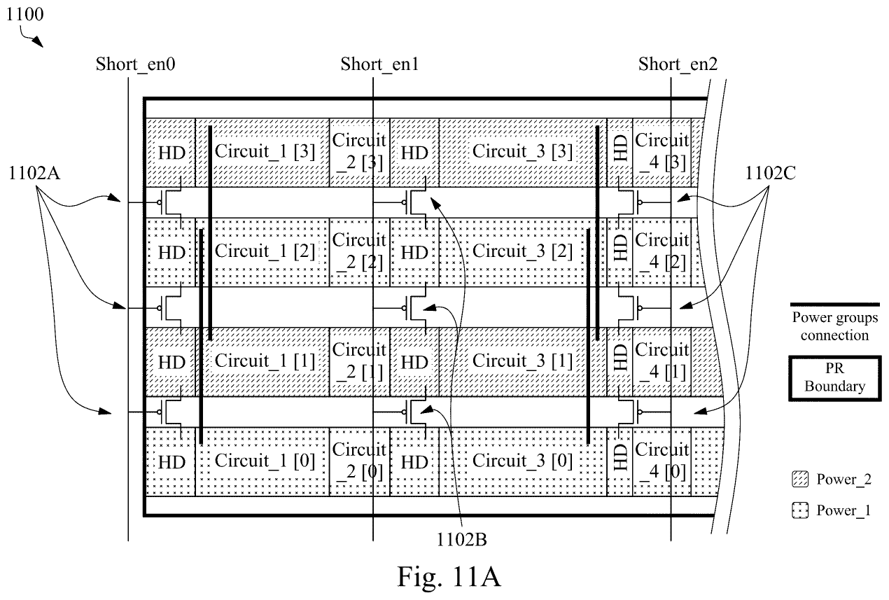

FIG. 10 illustrates a diagram of the example integrated circuit of at least one of FIGS. 1A-B or FIGS. 5A-B, including variations in configurations of tiling cells to adjust the partitioning of power domains, in accordance with some embodiments. As shown, multiple variations in the connection configurations between circuits of layout 1000 can be provided by attaching different tiling cell to make adjustments. Tiling cells can be used to adjust the partitioning of power domains and manage the connections between different circuits. The configurations of tiling cells may vary to provide flexibility in combining or splitting of the power domains, and connection of circuits within the layout. The usage of the tiling cell to adjust the partitioning of power domains in an integrated circuit can be shown in or described in conjunction with at least FIG. 10.

For example, in configuration 1002 (e.g., tiling_cell_A), the four power domains including the circuits (e.g., Circuit_1 [0]-[3] and Circuit_2 [0]-[3]) in layout 1000 can be combined to two power domains. In the first power domain of configuration 1002, the power groups connection can electrically couple power supplier groups associated with Circuit_1 [0], [2] and Circuit_2 [1], [3]. In the second power domain of configuration 1002, the power groups connection can electrically couple power supplier groups associated with Circuit_1 [1], [3] and Circuit_2 [0], [2].

The configurations 1004, 1006 (e.g., tiling_cell_B and tiling_cell_C, respectively) can provide example connections between circuits for splitting the power supplier group (e.g., power domain) into four parts. In configurations 1004, 1006, one or more circuits can be coupled other circuits in different layers of the stack of circuits. For example, the power groups connections can couple Circuit_1 [0] and Circuit_2 [1], Circuit_1 [1] and Circuit_2 [2], and Circuit_1 [2] and Circuit_2 [3]. In configuration 1004, the power groups connections can remain within the PR boundary, such that Circuit_1 [3] can be configured to couple with Circuit_2 [0], e.g., described in conjunction with at least FIG. 7. In configuration 1004, the power groups connections can extend to circuits outside the PR boundary, such that Circuit_1 [3] can couple with Circuit_3 [0] and Circuit_1 [0] can couple with Circuit_0 [3], for example, such as described in conjunction with at least FIG. 8.

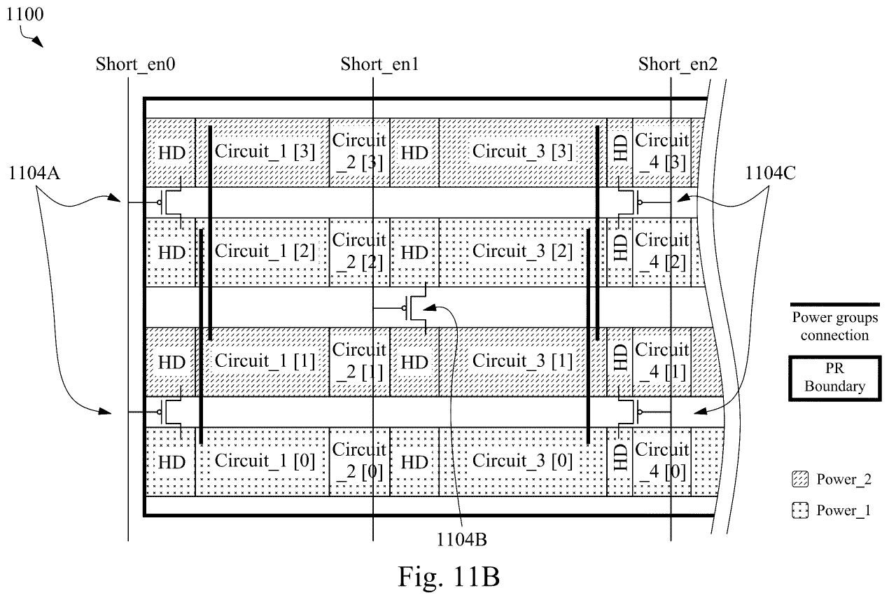

FIGS. 11A-B illustrate diagrams of the example integrated circuit of at least one of FIGS. 1A-B or FIGS. 5A-B, including one or more transistors 1102A-C or 1104A-C to short split power mesh (e.g., combining power domains), in accordance with some embodiments. FIGS. 11A-B include IC 1100. The IC 1100 can include one or more components similar to or different from other ICs described in conjunction with at least one of FIGS. 1A-10, etc. For purposes of providing examples, the IC 1100 can include the circuits, power groups connections, and other components similar to the IC 400 of FIG. 4.

In some configurations, the IC 1100 can include or add transistors 1102A-C or 1104A-C to short split power mesh, for instance, for combining power domains between the layers of circuits in the stack. The transistors 1102A-C can sometimes be referred to as transistor(s) 1102. The transistors 1104A-C can sometimes be referred to as transistor(s) 1104. The transistors 1102, 1104 can be PMOS, NMOS, or other types of MOSFET. For examples herein, PMOS transistors can be added or implemented for shorting split power mesh.

For example, in FIG. 11A, the IC 1100 can include transistors 1102 coupled between adjacent layers in the stack of circuits. The transistors 1102A can couple the HDs associated with Circuit_1 [0]-[3] and/or Circuit_2 [0]-[3] when activated. The transistors 1102B can couple the HDs associated with Circuit_3 [0]-[3] when activated. The transistors 1102C can couple the HDs associated with Circuit_4 [0]-[3] when activated. In this case, the transistors 1102A-C (for PMOS) can be deactivated by sending a high signal (e.g., ‘1’ or a predefined voltage) and activated by sending a low signal (e.g., ‘0’ or no voltage).

In response to activating the respective transistors 1102, power mesh or lines between the circuits or HDs can be shorted, allowing the corresponding circuits (described above) to receive supply voltage from the same power supply. When the transistors 1102 are deactivated, the power domain can be separated to prevent competition for electrical resources. As shown, signals from Short_en0, Short_en1, and Short_en2 can be used to control the transistors 1102A-C, respectively.

Similar operations of the transistors 1102 can be applied to the transistors 1104. Signals from Short_en0, Short_en1, and Short_en2 can be used to control the transistors 1104A-C, respectively. For example, activating the transistors 1104A can short the power supply to Circuit_1 [0]-[3] and Circuit_2 [0]-[3], thereby allowing the circuits to operate in a single power domain. Similarly, activating the transistors 1104C can short the power supply to Circuit_4 [0]-[3], allowing these circuits to operate in a single power domain. When activating the transistor 1104B, the power supply to Circuit_3 [1]-[2] can be shorted, allowing the circuits to operate under the same power domain (e.g., operating in one or a combination of the first power domain and/or the second power domain, etc.). The Circuit_3 [0] and Circuit_3 [3] may operate in their respective power domain. As such, by adding the transistors 1102, 1104, the systems and methods of the technical solution can allow for configurable combining or separating of power domains by dynamically shorting split power mesh. The placement of the transistors can be flexible and vary depending on the design or configurations of the ICs, e.g., designs for minimizing gate delay or managing IR drop. For example, strategically placing transistors can help reduce signal propagation times and maintain stable supply voltages, thereby enhancing the overall performance and reliability of the integrated circuit.

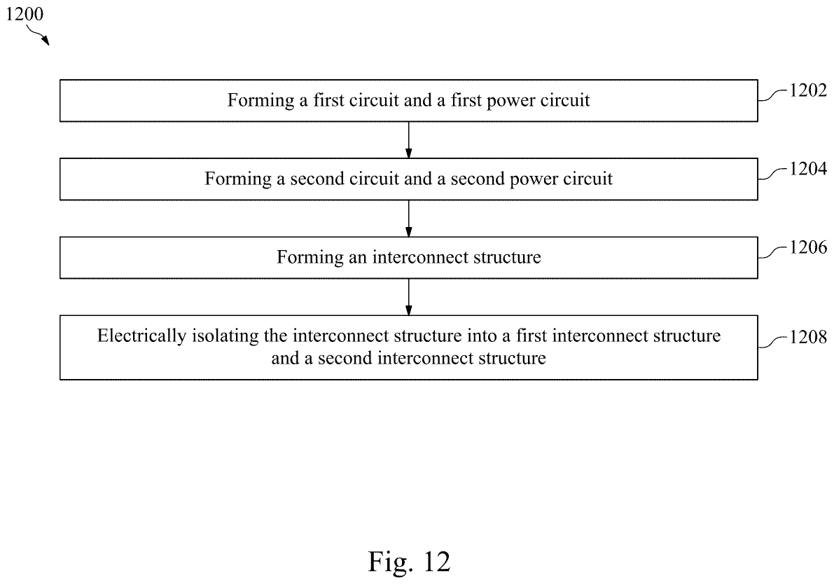

FIG. 12 illustrates a flow chart of an example method 1200 for forming an integrated circuit (e.g., IC 100, 200A-B, 300, 400, 500, etc.), in accordance with some embodiments. For example, the method 1200 can include operations, features, or components to fabricate or form the integrated circuit(s) as discussed with respect to at least one of but not limited to FIGS. 1A-11. As such, the following embodiment of the method 1200 will be described in conjunction with FIGS. 1A-11. The illustrated embodiment of the method 1200 is merely an example. Therefore, it shall be understood that any of a variety of the operations of the method 1200 may be omitted, re-sequenced, and/or added while remaining within the scope of the present disclosure.

The method 1200 starts with operation 1202 of forming a first circuit and a first power circuit. For example, the method 1200 can include forming a first circuit (e.g., 102A) in a first region (e.g., 101B) along a major surface of a substrate. The major surface can refer to the topmost layer of the substrate. The first circuit can be configured to operate with a first supply voltage (e.g., a first predefined power level to consume from the power supply).

The method 1200 can include forming a first power circuit (e.g., 104A such as a header) in a second region (e.g., 101A) along the major surface. The first power circuit can be configured to selectively provide the first supply voltage to the first circuit. For instance, the first power circuit (or other power circuits herein) can be configured to control the power supply from a power source (e.g., internal or external to the IC) to at least the first circuit. In some configuration, the first power circuit (or other power circuits) can control the power supply from the power source to multiple circuits.

Next, the method 1200 proceeds to operation 1204 of forming a second circuit and a second power circuit. The method 1200 can include forming a second circuit (e.g., 102B) in a third region (e.g., 101D) along the major surface. The second circuit can be configured to operate with a second supply voltage, e.g., a second predefined power level. The first circuit and the second circuit can have different power consumption levels. Other circuits may have similar or different power consumption levels relative to the first circuit and/or the second circuit.

The method 1200 can include forming a second power circuit (e.g., 104C) in a fourth region (e.g., 101E) along the major surface. The second power circuit can be configured to selectively provide the second supply voltage to the second circuit. The first region and the third region can be located adjacent to each other along a lateral direction. Along the lateral direction, the second region can be located opposite the first region from the third region and the fourth region can be located opposite the third region from the first region.

In some configurations, a third power circuit (e.g., 104B) can be formed, interposed between the first circuit and the second circuit along the lateral direction. The third power circuit can be formed in a fifth region (e.g., 101C) between the first and third regions. In some cases, the third power circuit may be provided for design purposes, e.g., disconnected from the first and second circuits. In some cases, the third power circuit may be electrically coupled to at least one of the first circuit, the second circuit, or other circuits to selectively provide the respective supply voltage.

The method 1200 continues to operation 1206 of forming at least one interconnect structure (e.g., interconnect structure 106, 202, or 506). For example, the method 1200 can include forming an interconnect structure (e.g., 106) in a first one of a plurality of metallization layers over the major surface. The IC can include metallization layers formed above the major surface, where each of the metallization layers include metal structures formed to provide connections between components or to external components, for example. In this case, the interconnect structure can represent a metal track or power line carrying power supply from a power source.

Subsequently, the method 1200 proceeds to operation 1208 of electrically isolating the interconnect structure into a first interconnect structure (e.g., interconnect structure 106A) and a second interconnect structure (e.g., interconnect structure 106B). For example, the method 1200 can include electrically isolating the interconnect structure into a first interconnect structure (e.g., 106A) and a second interconnect structure (e.g., 106B) with at least one isolation structure (e.g., 112). The isolation structure can be formed by executing a directional etching to cut the interconnect structure (e.g., MTO) to form an opening. The opening can be filled with a dielectric material, thereby electrically isolating the separated portions (e.g., 106A, 106B) of the interconnect structure (e.g., 106). The at least one isolation structure can be disposed over the third power circuit. The at least one isolation structure can be formed in the first metallization layer between the first interconnect structure and the second interconnect structure. By electrically isolating the interconnect structure into the two portions, separate power domains can be provided to prevent competition for power resources between the two circuits.

The first interconnect structure can be configured to electrically couple the first power circuit to the first circuit. The second interconnect structure can be configured to electrically couple the second power circuit to the second circuit. The circuits and power circuits can be electrically coupled to the first and second interconnect structures via a plurality of connections (e.g., polysilicon or other materials). The first and second interconnect structures can both extend along the lateral direction.

The method 1200 can include forming a third interconnect structure (e.g., 110, MT2) in a second one of the plurality of metallization layers over the first metallization layer. The method 1200 can include electrically coupling the first interconnect structure and the second interconnect structure with at least the third interconnect structure. The first to third interconnect structures can all extend along a same lateral direction.

The coupling between the first and second interconnect structures to the third interconnect structure can be interposed by one or more other interconnect structures. For example, The method 1200 can include forming a fourth interconnect structure (e.g., 108A or 108B, e.g., MT1) in a third one of the plurality of metallization layers between the first metallization layer and the second metallization layer. In this case, the third metallization layer can refer to a layer above the first metallization layer and below the second metallization layer. The fourth interconnect structure can be electrically coupled to the first interconnect structure and the third interconnect structure. The method 1200 can include forming a fifth interconnect structure (e.g., 108C or 108D, e.g., another MT1) formed in the third metallization layer. The fifth interconnect structure can be electrically coupled to the second interconnect structure and the third interconnect structure. The coupling between interconnect structures can be through at least one via structure (e.g., VIA0, VIA1, etc.). The fourth interconnect structure and the fifth interconnect structure can extend along another lateral direction (e.g., a second lateral direction or a longitudinal direction) perpendicular to the first to third interconnect structures.

In some configurations, the method 1200 can include forming a third circuit (e.g., 102C) in a sixth region along the major surface. The method 1200 can include forming a fourth circuit (e.g., 102D) in a seventh region along the major surface. The method 1200 can include forming a sixth interconnect structure (e.g., 202C) in the first metallization layer. The sixth interconnect structure can be configured to electrically couple the third circuit to one of the first power circuit, the second power circuit, or another power circuit different from the first and second power circuits. The method 1200 can include forming a seventh interconnect structure (e.g., 202D) formed in the first metallization layer. The seventh interconnect structure can be configured to electrically couple the fourth circuit to one of the first power circuit, the second power circuit, or another power circuit different from the first and second power circuits. In some implementations, the first power circuit and/or the second power circuit may be configured to selectively provide multiple supply power to multiple circuits, for example. The first, second, sixth, and seventh interconnect structures can be electrically isolated from each other with a plurality of isolation structures (e.g., 112A-C). With the electrical isolation in such cases, four power domains can be provided to further prevent competition for power resources between the four circuits.

In some cases, the third circuit can be configured to operate with a third supply voltage and the fourth circuit can be configured to operate with a fourth supply voltage. The third and fourth supply voltages can be different from each other and the first and second supply voltages. In such cases, the first, second, sixth, and seventh interconnect structures can be electrically coupled to each other with at least the third interconnect structure (e.g., 110), e.g., for communication between the first to fourth circuits/devices.

In some other cases, the method 1200 can include forming an eighth interconnect structure (e.g., 204B) in the second metallization layer. For example, the third circuit can be configured to operate with the first supply voltage, similar to the first circuit. The fourth circuit can be configured to operate with the second supply voltage, similar to the second circuit. In such cases, the method 1200 can arrange the connections to split the power supplier group into two parts (e.g., for two power domains). The first interconnect structure (e.g., 202A) and the sixth interconnect structure (e.g., 202C) are electrically coupled to each other with at least the third interconnect structure (e.g., 204A). The second interconnect structure (e.g., 202B) and the seventh interconnect structure (e.g., 202D) can be electrically coupled to each other with at least the eighth interconnect structure (e.g., 204B). The seventh and eighth interconnect structures can be configured to short or combine the transistors or power lines associated with the power circuits configured to selectively provide the supply power to the respective circuits, such that the first and third circuits can receive the first supply voltage and the second and fourth circuits can receive the second supply voltage. Other layouts or interconnections between components can be implemented, not limited to those discussed herein.

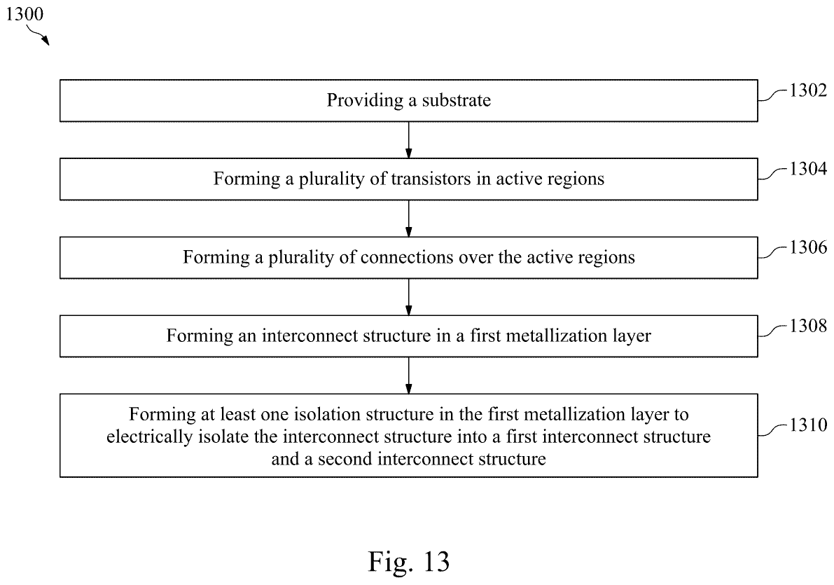

FIG. 13 illustrates a flow chart of an example method 1300 for forming an integrated circuit (e.g., IC 100, 200A-B, 300, 400, 500, etc.), in accordance with some embodiments. For example, the method 1300 can include operations, features, or components to fabricate or form the integrated circuit(s) as discussed with respect to at least one of but not limited to FIGS. 1A-11. As such, the following embodiment of the method 1300 will be described in conjunction with FIGS. 1A-11. The illustrated embodiment of the method 1300 is merely an example. Therefore, it shall be understood that any of a variety of the operations of the method 1300 may be omitted, re-sequenced, and/or added while remaining within the scope of the present disclosure. In some configurations, the operations of method 1300 can include one or more operations similar to (or in some cases different from) method 1200, as described in conjunction with at least FIG. 12.

The method 1300 starts with operation 1302 of providing (or forming) a substrate comprising a major surface. The substrate can be composed of any suitable material, such as but not limited to at least one of silicon, gallium nitride, gallium arsenide, or germanium. The major surface of the substrate can refer to the face (e.g., top or bottom face) of the substrate, which may be parallel to the wafer plane, for example.

Next, the method 1300 proceeds to operation 1304 of forming a plurality of transistors in active regions along the major surface of the substrate. The active regions can refer to the portion of the integrated device or circuit where at least a portion of the electrical operations occur, such as current conduction, amplification, switching, etc. The plurality of transistors formed in the active regions can be electrically coupled or configured with each other to form one or more circuits. For example, the plurality of transistors can form a first circuit (e.g., 102A) in a first region (e.g., 101B) of the active regions, a first power circuit (e.g., 104A) in a second region (e.g., 101A) of the active regions, a second circuit (e.g., 102B) in a third region (e.g., 101D) of the active regions, and a second power circuit (e.g., 104C) in a fourth region (e.g., 101E) of the active regions.

The first to fourth regions can be located along a lateral direction. Along the lateral direction, the second region can be located opposite the first region from the third region and the fourth region can be located opposite the third region from the first region. The plurality of transistors can form other circuits (or less circuits) not limited to the first and second circuits, and the first and second power circuits. In some cases, the plurality of transistors formed in the active regions may be configured to electrically couple with one or more other transistors, not limited to those discussed herein.

The method 1300 proceeds to operation 1306 of forming a plurality of connections over the active regions. The connections can be composed of any suitable materials, such as polysilicon, among others. The connections can be used to form gate structures of transistors for electrical connections between components. The connections can be used to electrically couple the transistors (associated with the circuit(s)) to each other. In some cases, the connections can be used to electrically couple the transistors to other non-limiting transistors, devices, components, or structures.

The method 1300 continues to operation 1308 of forming an interconnect structure (e.g., interconnect structure 106, 202, or 506) in a first one of a plurality of metallization layers (e.g., first metallization layer or MT0) over the plurality of connections and the active regions. The IC can include metallization layers formed above the major surface, where each of the metallization layers include metal structures formed to provide connections between components or to external components, for example. At least a portion of the plurality of transistors can be electrically coupled to other transistors via the plurality of connections and the interconnect structure. The interconnect structure can represent a metal track or power line carrying power supply from a power source.

Next, the method 1300 continues to operation 1310 of forming at least one isolation structure in the first metallization layer to electrically isolate the interconnect structure into at least two portions, e.g., a first interconnect structure and a second interconnect structure. To form the isolation structure, the method 1300 can involve etching at least a portion of the interconnect structure, thereby separating the interconnect structure into at least two portions. In this case, the first portion can be referred to as the first interconnect structure and the second portion can be referred to as the second interconnect structure. Any suitable etching technique can be utilized. Once the portion (or an opening) is formed, the method 1300 can involve depositing the isolation structure into the etched portion to electrically isolate the first interconnect structure and the second interconnect structure. Any suitable deposition technique can be utilized. The isolation structure can be composed of any suitable non-conductive materials.

The power circuits can be configured to selectively provide supply voltage respective circuits via the interconnect structure. For example, the first circuit can be configured to operate with a first supply voltage (e.g., a first predefined power level to consume from the power supply). The first power circuit can be configured to selectively provide the first supply voltage to the first circuit. The second circuit can be configured to operate with a second supply voltage, e.g., a second predefined power level. The second power circuit can be configured to selectively provide the second supply voltage to the second circuit. The power circuits can be configured to can be configured to control the power supply from a power source (e.g., internal or external to the IC) to at least one circuit. The power (or voltage) from the first power circuit can be supplied to the first circuit via respective connections and the first interconnect structure. The power from the second power circuit can be supplied to the second circuit via respective connections and the second interconnect structure.

In various configurations, the method 1300 can include forming a plurality of via structures (e.g., VIA1 or VIA2) over the first metallization layer. The method 1300 can include forming a third interconnect structure (e.g., 110, MT2) in a second one of the plurality of metallization layers (e.g., second metallization layer) over the first metallization layer and the via structures. Through one or more of the via structures and the third interconnect structure, the first interconnect structure can be electrically coupled to the second interconnect structure. It should be noted that other structures, components, or materials can be formed in the IC, not limited to those discussed herein.

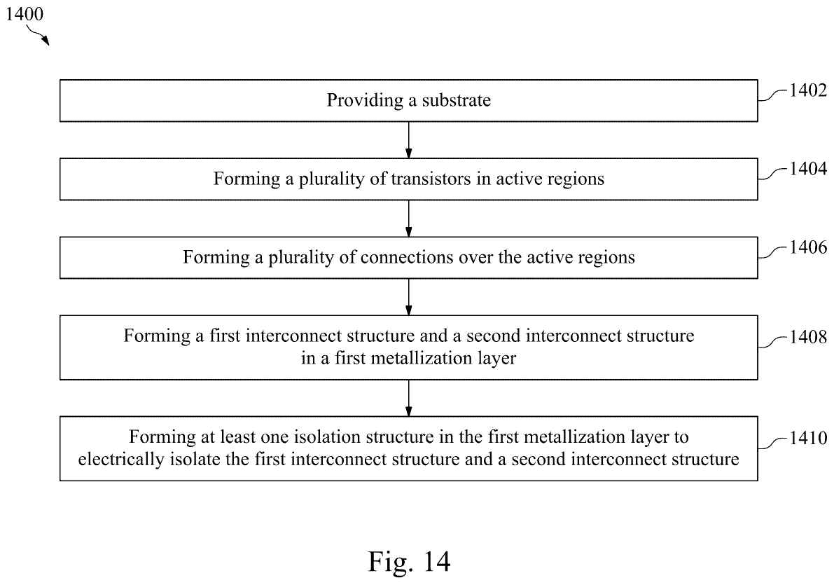

FIG. 14 illustrates a flow chart of an example method 1400 for forming an integrated circuit (e.g., IC 100, 200A-B, 300, 400, 500, etc.), in accordance with some embodiments. For example, the method 1400 can include operations, features, or components to fabricate or form the integrated circuit(s) as discussed with respect to at least one of but not limited to FIGS. 1A-11. As such, the following embodiment of the method 1400 will be described in conjunction with FIGS. 1A-11. The illustrated embodiment of the method 1400 is merely an example. Therefore, it shall be understood that any of a variety of the operations of the method 1400 may be omitted, re-sequenced, and/or added while remaining within the scope of the present disclosure. In some configurations, the operations of method 1400 can include one or more operations similar to (or in some cases different from) method 1200 and/or method 1300, as described in conjunction with at least FIG. 12 and/or FIG. 13.

The method 1400 starts with operation 1402 of providing (or forming) a substrate comprising a major surface. The substrate can be composed of any suitable material, such as but not limited to at least one of silicon, gallium nitride, gallium arsenide, or germanium. The major surface of the substrate can refer to the face (e.g., top or bottom face) of the substrate, which may be parallel to the wafer plane, for example.

Next, the method 1400 proceeds to operation 1404 of forming a plurality of transistors in active regions along the major surface of the substrate. The active regions can refer to the portion of the integrated device or circuit where at least a portion of the electrical operations occur, such as current conduction, amplification, switching, etc. The plurality of transistors formed in the active regions can be electrically coupled or configured with each other to form one or more circuits. For example, the plurality of transistors can form a first circuit (e.g., 102A) in a first region (e.g., 101B) of the active regions, a first power circuit (e.g., 104A) in a second region (e.g., 101A) of the active regions, a second circuit (e.g., 102B) in a third region (e.g., 101D) of the active regions, and a second power circuit (e.g., 104C) in a fourth region (e.g., 101E) of the active regions.

The first to fourth regions can be located along a lateral direction. Along the lateral direction, the second region can be located opposite the first region from the third region and the fourth region can be located opposite the third region from the first region. The plurality of transistors can form other circuits (or less circuits) not limited to the first and second circuits, and the first and second power circuits. In some cases, the plurality of transistors formed in the active regions may be configured to electrically couple with one or more other transistors, not limited to those discussed herein.

The method 1400 proceeds to operation 1406 of forming a plurality of connections over the active regions. The connections can be composed of any suitable materials, such as polysilicon, among others. The connections can be used to form gate structures of transistors for electrical connections between components. The connections can be used to electrically couple the transistors (associated with the circuit(s)) to each other. In some cases, the connections can be used to electrically couple the transistors to other non-limiting transistors, devices, components, or structures.

The method 1400 continues to operation 1408 of forming a first interconnect structure (e.g., 106A, 202A, or 506A) and a second interconnect structure (e.g., 106B, 202B, or 506B) in a first one of a plurality of metallization layers (e.g., first metallization layer or MT0) over the plurality of connections and the active regions. The IC can include metallization layers formed above the major surface, where each of the metallization layers include metal structures formed to provide connections between components or to external components, for example. At least a portion of the plurality of transistors can be electrically coupled to other transistors via the plurality of connections and the interconnect structure. The interconnect structure can represent a metal track or power line carrying power supply from a power source. The first interconnect structure can be formed over the first region and the second region of the active regions, e.g., over the first circuit and the first power circuit. The second interconnect structure can be formed over the third region and the fourth region of the active regions, e.g., over the second circuit and the second power circuit.

Next, the method 1400 continues to operation 1410 of forming at least one isolation structure in the first metallization layer to electrically isolate the first interconnect structure and the second interconnect structure. For example, the first interconnect structure and second interconnect structure can be formed in different regions or portions of the first metallization layer, where the first and second interconnect structures can be separated by a gap or an opening. To form the isolation structure, the method 1300 can involve depositing the isolation structure into the opening to electrically isolate the first interconnect structure and the second interconnect structure. Any suitable deposition technique can be utilized. The isolation structure can be composed of any suitable non-conductive materials.

The power circuits can be configured to selectively provide supply voltage respective circuits via the first and/or second interconnect structures (among other interconnect structures). For example, the first circuit can be configured to operate with a first supply voltage (e.g., a first predefined power level to consume from the power supply). The first power circuit can be configured to selectively provide the first supply voltage to the first circuit. The second circuit can be configured to operate with a second supply voltage, e.g., a second predefined power level. The second power circuit can be configured to selectively provide the second supply voltage to the second circuit. The power circuits can be configured to can be configured to control the power supply from a power source (e.g., internal or external to the IC) to at least one circuit. The power (or voltage) from the first power circuit can be supplied to the first circuit via respective connections and the first interconnect structure. The power from the second power circuit can be supplied to the second circuit via respective connections and the second interconnect structure.

In various configurations, the method 1300 can include forming a plurality of via structures (e.g., VIA1 or VIA2) over the first metallization layer. The method 1300 can include forming a third interconnect structure (e.g., 110, MT2) in a second one of the plurality of metallization layers (e.g., second metallization layer) over the first metallization layer and the via structures. Through one or more of the via structures and the third interconnect structure, the first interconnect structure can be electrically coupled to the second interconnect structure. It should be noted that other structures, components, or materials can be formed in the IC, not limited to those discussed herein.

In one aspect of the present disclosure, an integrated circuit includes a first circuit configured to operate with a first supply voltage, wherein the first circuit is formed in a first region along a major surface of a substrate. The integrated circuit includes a first power circuit configured to selectively provide the first supply voltage to the first circuit, wherein the first power circuit is formed in a second region along the major surface. The integrated circuit includes a second circuit configured to operate with a second supply voltage, wherein the second circuit is formed in a third region along the major surface. The integrated circuit includes a second power circuit configured to selectively provide the second supply voltage to the second circuit, wherein the second power circuit is formed in a fourth region along the major surface. The integrated circuit includes a first interconnect structure formed in a first one of a plurality of metallization layers over the major surface, wherein the first interconnect structure is configured to electrically couple the first power circuit to the first circuit. The integrated circuit includes a second interconnect structure formed in the first metallization layer, wherein the second interconnect structure is configured to electrically couple the second power circuit to the second circuit. The first interconnect structure and the second interconnect structure are electrically isolated from each other with at least one isolation structure.

In another aspect of the present disclosure, an integrated circuit. The integrated circuit includes a plurality of circuits, each configured to operate with at least one of a first supply voltage or a second supply voltage, wherein the plurality of circuits are formed along a major surface of a substrate. The integrated circuit includes a plurality of power circuits, each configured to selectively provide one of at least the first supply voltage or the second supply voltage to a respective one of the plurality of circuits, wherein the plurality of power circuits are formed along the major surface. The integrated circuit includes a plurality of interconnect structures formed in a first metallization layer of a plurality of metallization layers over the major surface, each of the plurality of interconnect structures configured to electrically couple one of the plurality of power circuits to at least one of the plurality of circuits. The plurality of interconnect structures are electrically isolated from each other with at least one isolation structure.

In yet another aspect of the present disclosure, a method for forming an integrated circuit. The method includes providing a substrate comprising a major surface. The method includes forming a plurality of transistors in active regions along the major surface of the substrate, wherein the plurality of transistors form a first circuit in a first region of the active regions, a first power circuit in a second region of the active regions, a second circuit in a third region of the active regions, and a second power circuit in a fourth region of the active regions. The method includes forming a plurality of connections over the active regions. The method includes forming a first interconnect structure and a second interconnect structure in a first one of a plurality of metallization layers over the plurality of connections and the active regions, wherein at least a portion of the plurality of transistors is electrically coupled to other transistors via the plurality of connections and the first and second interconnect structures. The method includes forming, in the first metallization layer, at least one isolation structure to electrically isolate the first interconnect structure and the second interconnect structure, wherein the first power circuit is configured to selectively provide the first supply voltage to the first circuit via the first interconnect structure, and wherein the second power circuit is configured to selectively provide the second supply voltage to the second circuit via the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit, comprising:
a first circuit configured to operate with a first supply voltage, wherein the first circuit is formed in a first region along a major surface of a substrate;
a first power circuit configured to selectively provide the first supply voltage to the first circuit, wherein the first power circuit is formed in a second region along the major surface;
a second circuit configured to operate with a second supply voltage, wherein the second circuit is formed in a third region along the major surface;
a second power circuit configured to selectively provide the second supply voltage to the second circuit, wherein the second power circuit is formed in a fourth region along the major surface;
a first interconnect structure formed in a first one of a plurality of metallization layers over the major surface, wherein the first interconnect structure is configured to electrically couple the first power circuit to the first circuit; and
a second interconnect structure formed in the first metallization layer, wherein the second interconnect structure is configured to electrically couple the second power circuit to the second circuit,
wherein the first interconnect structure and the second interconnect structure are electrically isolated from each other with at least one isolation structure.

2. The integrated circuit of claim 1, wherein the at least one isolation structure is formed in the first metallization layer.

3. The integrated circuit of claim 1, wherein, along a lateral direction, the first region and the third region are located adjacent to each other, with the second region located opposite the first region from the third region and with the fourth region located opposite the third region from the first region.

4. The integrated circuit of claim 3, further comprising:
a third power circuit interposed between the first circuit and the second circuit along the lateral direction.

5. The integrated circuit of claim 4, wherein the at least one isolation structure is disposed over the third power circuit.

6. The integrated circuit of claim 3, wherein the first and second interconnect structures both extend along the lateral direction.

7. The integrated circuit of claim 1, further comprising:
a third interconnect structure formed in a second one of the plurality of metallization layers over the first metallization layer;
wherein the first interconnect structure and the second interconnect structure are electrically coupled to each other with at least the third interconnect structure.

8. The integrated circuit of claim 7, wherein the first to third interconnect structures all extend along a same lateral direction.

9. The integrated circuit of claim 1, further comprising:
a fourth interconnect structure formed in a third one of the plurality of metallization layers between the first metallization layer and the second metallization layer, wherein the fourth interconnect structure is electrically coupled to the first interconnect structure and a third interconnect structure; and
a fifth interconnect structure formed in the third metallization layer, wherein the fifth interconnect structure is electrically coupled to the second interconnect structure and the third interconnect structure,
wherein the fourth interconnect structure and the fifth interconnect structure extend along another lateral direction perpendicular to the first to third interconnect structures.

10. The integrated circuit of claim 1, wherein the first circuit and the second circuit have different power consumption levels.

11. The integrated circuit of claim 1, further comprising:
a third circuit formed in a sixth region along the major surface;
a fourth circuit formed in a seventh region along the major surface;
a sixth interconnect structure formed in the first metallization layer, wherein the sixth interconnect structure is configured to electrically couple the third circuit to one of the first power circuit, the second power circuit, or another power circuit different from the first and second power circuits; and
a seventh interconnect structure formed in the first metallization layer, wherein the seventh interconnect structure is configured to electrically couple the fourth circuit to one of the first power circuit, the second power circuit, or another power circuit different from the first and second power circuits,
wherein the first, second, sixth, and seventh interconnect structures are electrically isolated from each other with a plurality of isolation structures.

12. The integrated circuit of claim 11, wherein:
the third circuit is configured to operate with a third supply voltage,
the fourth circuit is configured to operate with a fourth supply voltage, and
the first, second, sixth, and seventh interconnect structures are electrically coupled to each other with at least the third interconnect structure.

13. The integrated circuit of claim 11, further comprising:
an eighth interconnect structure formed in the second metallization layer,
wherein:
the third circuit is configured to operate with the first supply voltage,
the fourth circuit is configured to operate with the second supply voltage,
the first interconnect structure and the sixth interconnect structure are electrically coupled to each other with at least the third interconnect structure, and
the second interconnect structure and the seventh interconnect structure are electrically coupled to each other with at least the eighth interconnect structure.

14. An integrated circuit, comprising:
a plurality of circuits, each configured to operate with at least one of a first supply voltage or a second supply voltage, wherein the plurality of circuits are formed along a major surface of a substrate;
a plurality of power circuits, each configured to selectively provide one of at least the first supply voltage or the second supply voltage to a respective one of the plurality of circuits, wherein the plurality of power circuits are formed along the major surface;
a plurality of interconnect structures formed in a first metallization layer of a plurality of metallization layers over the major surface, each of the plurality of interconnect structures configured to electrically couple one of the plurality of power circuits to at least one of the plurality of circuits,
wherein the plurality of interconnect structures are electrically isolated from each other with at least one isolation structure.

15. The integrated circuit of claim 14, wherein:
the plurality of circuits comprise a first circuit and a second circuit,
the plurality of power circuits comprise a first power circuit and a second power circuit, and
the plurality of interconnect structures comprise a first interconnect structure and a second interconnect structure electrically isolated from each other with a first isolation structure, the first interconnect structure is configured to electrically couple the first power circuit to the first circuit, and the second interconnect structure is configured to electrically couple the second power circuit to the second circuit.

16. The integrated circuit of claim 15, wherein:
the plurality of circuits further comprise a third circuit and a fourth circuit,
the plurality of power circuits further comprise a third power circuit, and
the plurality of interconnect structures further comprise a third interconnect structure and a fourth interconnect structure electrically isolated from each other with a second isolation structure and electrically isolated from the first and second interconnect structures with a third isolation structure, the third interconnect structure is configured to electrically couple one of the first to third power circuits to the third circuit, and the fourth interconnect structure is configured to electrically couple one of the first to third power circuits to the fourth circuit.

17. The integrated circuit of claim 14, further comprising:
a fifth interconnect structure and a sixth interconnect structure formed in a second metallization layer of the plurality of metallization layers over the first metallization layer, wherein one of:
the first to fourth interconnect structures are electrically coupled to each other with at least the fifth interconnect structure, or
the first and third interconnect structures are electrically coupled to each other with at least the fifth interconnect structure, and the second and fourth interconnect structures are electrically coupled to each other with at least the sixth interconnect structure.

18. A method for forming an integrated circuit, comprising:
providing a substrate comprising a major surface;
forming a plurality of transistors in active regions along the major surface of the substrate, wherein the plurality of transistors form a first circuit in a first region of the active regions, a first power circuit in a second region of the active regions, a second circuit in a third region of the active regions, and a second power circuit in a fourth region of the active regions;
forming a plurality of connections over the active regions;
forming a first interconnect structure and a second interconnect structure in a first one of a plurality of metallization layers over the plurality of connections and the active regions, wherein at least a portion of the plurality of transistors is electrically coupled to other transistors via the plurality of connections and the first and second interconnect structures; and
forming, in the first metallization layer, at least one isolation structure to electrically isolate the first interconnect structure and the second interconnect structure, wherein the first power circuit is configured to selectively provide the first supply voltage to the first circuit via the first interconnect structure, and wherein the second power circuit is configured to selectively provide the second supply voltage to the second circuit via the second interconnect structure.

19. The method of claim 18, wherein forming the at least one isolation structure comprises:
depositing the at least one isolation structure between the first interconnect structure and the second interconnect structure to electrically isolate the first interconnect structure and the second interconnect structure.

20. The method of claim 18, further comprising:
forming a plurality of via structures over the first metallization layer; and
forming a third interconnect structure in a second one of the plurality of metallization layers over the first metallization layer and the plurality of via structures,
wherein the first interconnect structure and the second interconnect structure are electrically coupled to each other through at least one or more of the plurality of via structures and the third interconnect structure.
